(19) United States
(12) Patent Application Publication
(10) Pub. No.: US 2024/0421821 A1
(43) Pub. Date: Dec. 19, 2024

(54) GPIO DRIVER WITH LOW LATENCY

(71) Applicant: MEDIATEK INC., Hsin-Chu (TW)

(72) Inventors: Federico Agustin Altolaguirre, Hsinchu City (TW); Yu-Shen Lin, Hsinchu City (TW)

(73) Assignee: MEDIATEK INC., Hsin-Chu (TW)

(21) Appl. No.: 18/739,245

(22) Filed: Jun. 10, 2024

Related U.S. Application Data
(60) Provisional application No. 63/508,295, filed on Jun. 15, 2023.

(51) Int. Cl. H03K 19/0185

(52) U.S. Cl. CPC H03K 19/018507

(57) ABSTRACT

The present invention provides a GPIO driver including a control logic, a level shifter module and a post-driver. The control logic supplied by a first supply voltage is configured to receive an input signal to generate a first signal. The level shifter module is configured to receive the first signal to generate a second signal. The post-driver supplied by a second supply voltage is configured to receive the second signal to generate an output signal. When the first supply voltage is lower than the second supply voltage, the level shifter module performs a level-boosting operation to increase a voltage level of the first signal to generate the second signal; and when the first supply voltage is greater than the second supply voltage, the level shifter module operates as a buffer, and the voltage level of the second signal is the same as the voltage level of the first signal.

### CROSS REFERENCE TO RELATED APPLICATIONS

This application claims the benefit of U.S. Provisional Application No. 63/508, 295, filed on Jun. 15, 2023. The content of the application is incorporated herein by reference.

### BACKGROUND

A general-purpose input/output (GPIO) driver comprises a control logic, a level shifter and a post-driver, wherein the level shifter is used to change a voltage level of a signal generated by the control logic to generate a level-shifted signal, and the post-driver is used to transmit the level-shifted signal to an external device. However, the level shifter usually causes higher propagation delay to the signal, especially when the voltage level of the level-shifted signal is lower than the voltage level of the signal (i.e., under-drive operation). As a result, the timing requirements for chip-to-chip communications may not be met.

### SUMMARY

It is therefore an objective of the present invention to provide a GPIO driver, which comprises an enhanced level shifter having shorter propagation delay when the GPIO driver performs the under-drive operation, to solve the above-mentioned problems.

According to one embodiment of the present invention, a GPIO driver comprising a control logic, a level shifter module and a post-driver is disclosed. The control logic is configured to receive an input signal to generate a first signal, wherein the control logic is supplied by a first supply voltage. The level shifter module is configured to receive the first signal to generate a second signal. The post-driver is configured to receive the second signal to generate an output signal, wherein the post-driver is supplied by a second supply voltage. In addition, when the first supply voltage is lower than the second supply voltage, the level shifter module performs a level-boosting operation to increase a voltage level of the first signal to generate the second signal; and when the first supply voltage is greater than the second supply voltage, the level shifter module operates as a buffer, and the voltage level of the second signal is the same as the voltage level of the first signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a GPIO driver according to one embodiment of the present invention.

FIG. 2 is a power selection signal generator according to one embodiment of the present invention.

FIG. 3 is a circuit structure of the level shifter module and the power switch according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

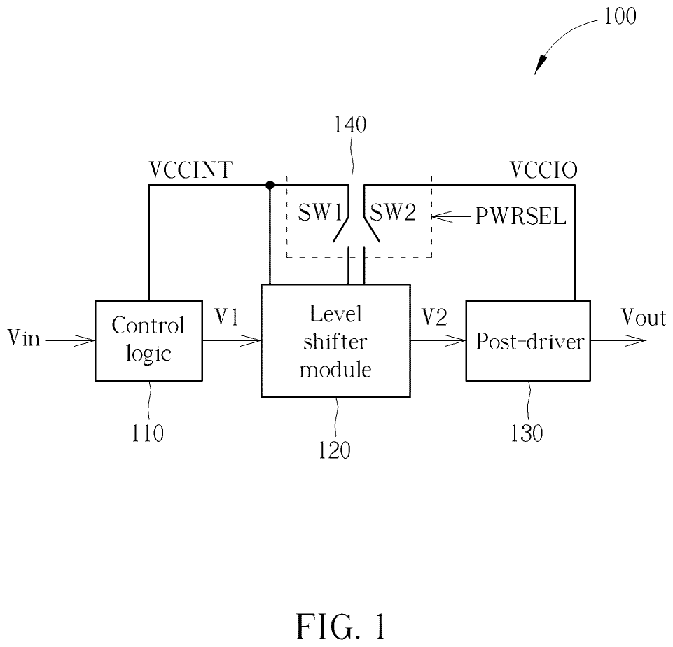

FIG. 1 is a diagram illustrating a GPIO driver 100 according to one embodiment of the present invention. As shown in FIG. 1, the GPIO driver 100 comprises a control logic 110, a level shifter module 120, a post-driver 130 and a power switch 140, wherein the power switch 140 comprises two switches SW1 and SW2 for selecting one of supply voltages VCCINT and VCCIO. In this embodiment, the GPIO driver 100 is within a chip, and the GPIO driver 100 is configured to receive an input signal Vin to generate an output signal Vout to an external device via a pin/pad of the chip.

In the operation of the GPIO driver 100, the control logic 110 comprises at least one logic circuit configured to receive the input signal to generate a first signal V1. The level shifter module 120 is configured to receive the first signal V1 to generate a second signal V2. The post-driver 130 is configured to receive the second signal V2 to generate the output signal Vout. As described in the background of the present invention, the conventional level-shift module may have higher latency (i.e., higher propagation delay to the signal) when the GPIO driver performs the under-drive operation, so the embodiment shown in FIG. 1 provides a special power configuration and circuit design for the level shifter module 120, to lower the latency of the GPIO driver 100.

Specifically, the control logic 110 is supplied by the supply voltage VCCINT, and the post-driver 130 is supplied by the supply voltage VCCIO, that is, the GPIO driver 100 is configured to receive the input signal Vin with the highest voltage level equal to VCCINT to generate the output signal Vout with the highest voltage level equal to VCCIO. The power switch 140 is configured to output one of the supply voltages VCCINT and VCCIO to the level shifter module 120 according a power selection signal PWRSEL. The level shifter module 120 has a first portion and a second portion, wherein the first portion is always supplied by the supply voltage VCCINT, and the second portion is supplied by the supply voltage VCCINT or VCCIO provided by the power switch 140. For example, when the supply voltage VCCINT is lower than the supply voltage VCCIO, the power selection signal PWRSEL controls the power switch 140 to select the supply voltage VCCIO with higher voltage level to the level shifter module 120, and the level shifter module 120 operates as a general level-boosting circuit to perform a level-boosting operation to increase a voltage level of the first signal V1 to generate the second signal V2. When the supply voltage VCCINT is higher than the supply voltage VCCIO, that is the GPIO driver 100 performs the under-drive operation, the power selection signal PWRSEL controls the power switch 140 to select the supply voltage VCCINT with higher voltage level to the level shifter module 120, and the level shifter module 120 operates as a buffer (i.e., the voltage level of the second signal V2 is the same as the voltage level of the first signal V1). Therefore, because the level shifter module 120 operates as the buffer instead of performing level-shifting operation, the signal propagation delay caused by the level shifter module 120 will be greatly reduced.

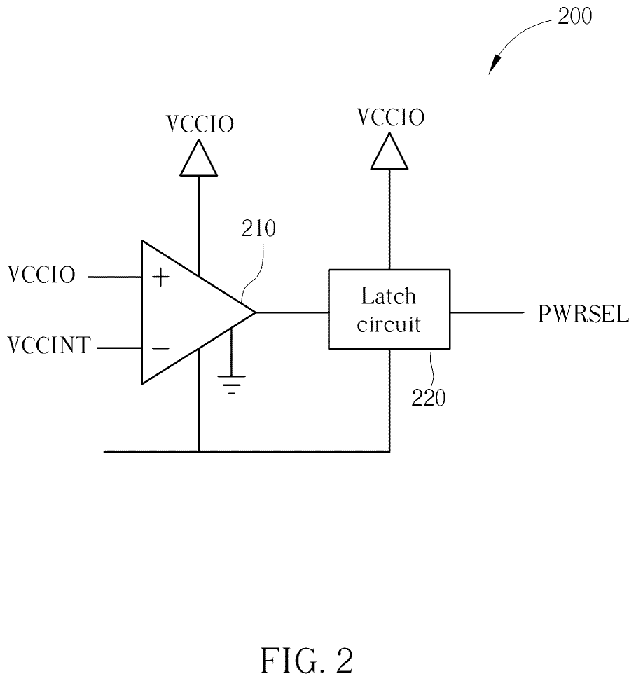

FIG. 2 is a power selection signal generator 200 according to one embodiment of the present invention. As shown in FIG. 2, the power selection signal generator 200 comprises a comparator 210 and a latch circuit 220 supplied by the supply voltage VCCIO. In the operation of the power selection signal generator 200, the comparator 210 compares the supply voltages VCCINT and VCCIO to generate a comparison result, for the latch circuit 220 to output the power selection signal PWRSEL. After the power selection signal PWRSEL is latched, a reset signal RESSET is asserted to disable the comparator 210 to lower the power consumption.

It is noted that the power selection signal generator 200 shown in FIG. 2 is for illustrative, not a limitation of the present invention. In other embodiments, the power selection signal generator 200 may have any other circuit design, or the power selection signal generator 200 may be a hardware setting. For example, a reference voltage having a specific voltage level corresponding to “0” or “1” may be directly used as the power selection signal PWRSEL.

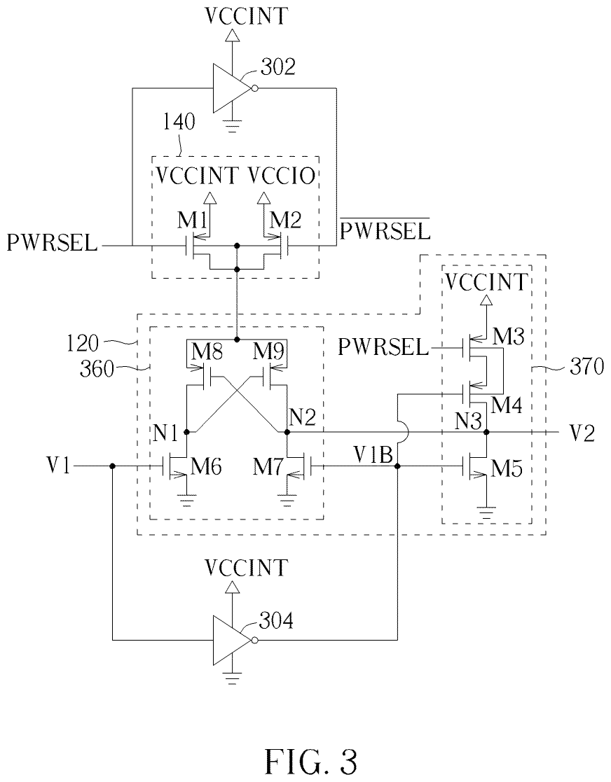

FIG. 3 is a circuit structure of the level shifter module 120 and the power switch 140 according to one embodiment of the present invention. As shown in FIG. 3, the power switch 140 comprises two transistors M1 and M2, wherein the transistor M1 serves as the switch SW1, and the transistor M2 serves as the switch SW2. In this embodiment, the transistor M1 is a P-type transistor controlled by the power selection signal PWRSEL, for selectively connecting the supply voltage VCCINT to the level shifter module 120; and the transistor M2 is a P-type transistor controlled by an inverted power selection signal P̅W̅R̅S̅E̅L̅ generated by using an inverter 302 to invert the power selection signal PWRSEL, for selectively connecting the supply voltage VCCIO to the level shifter module 120.

The level shifter module 120 comprises a level-shifting circuit 360 and an enhancement circuit 370. The level-shifting circuit 360 comprises four transistors M6-M9. The transistor M6 is an N-type transistor, wherein a gate electrode is connected to the first signal V1, a source electrode is connected to a ground voltage, and a drain electrode is coupled to a node N1. The transistor M7 is an N-type transistor, wherein a gate electrode is connected to an inverted first signal VIB generated by using an inverter 304 to invert the first signal V1, a source electrode is connected to the ground voltage, and a drain electrode is coupled to a node N2. The transistor M8 is a P-type transistor M8, wherein a gate electrode is coupled to the node N2, a source electrode is coupled to the supply voltage VCCINT or VCCIO provided by the power switch 140, and a drain electrode is coupled to the node N1. The transistor M9 is a P-type transistor M8, wherein a gate electrode is coupled to the node N1, a source electrode is coupled to the supply voltage VCCINT or VCCIO provided by the power switch 140, and a drain electrode is coupled to the node N2.

The enhancement circuit 370 comprises a charging circuit and a discharging circuit, wherein the charging circuit comprises two transistors M3 and M4, and the discharging circuit comprises a transistor M5. The transistor M3 is a P-type transistor, wherein a gate electrode is coupled to the power selection signal PWRSEL, and a source electrode is coupled to the supply voltage VCCINT. The transistor M4 is a P-type transistor, wherein a gate electrode is coupled to the inverted first signal V1B, a source electrode is coupled to a drain electrode of the transistor M3, and a drain electrode is coupled to a node N3. The transistor M5 is an N-type transistor, wherein a gate electrode is controlled by the inverted first signal V1B, a source electrode is coupled to the ground voltage, and a drain electrode is coupled to the node N3. In this embodiment, the node N3 is connected to N2, that is an output terminal of the level-shifting circuit 360 and an output terminal of the enhancement circuit 370 are connected together, and the node N2/N3 serves as an output terminal of the level shifter module 120. In addition, base electrodes of the transistors M3 and M4 are connected to the supply voltage VCCINT or VCCIO provided by the power switch 140.

Regarding the operation of the level shifter module 120 and the power switch 140 shown in FIG. 3, when the voltage level of the supply voltage VCCINT is lower than the voltage level of the supply voltage VCCIO, that is the GPIO driver 100 performs a level-boosting operation, the level-shifting circuit 360 operates as a level-boosting circuit, and the charging circuit of the enhancement circuit 370 (i.e., the transistors M3 and M4) is disabled. Specifically, when the supply voltage VCCINT is lower than the supply voltage VCCIO, the transistor M1 is disabled while the transistor M2 is enabled, so that the power switch 140 provides the supply voltage VCCIO to the level-shifting circuit 360. Because the level-shifting circuit 360 has the supply voltage VCCIO with higher voltage level, the second signal V2 generated by the level-shifting circuit 360 will have higher voltage level than the first signal V1 (i.e., high voltage level of the first signal V1 is VCCINT, and high voltage level of the second signal V2 is VCCIO greater than VCCINT). Meanwhile, the transistor M3 controlled by the power selection signal PWRSEL disabled, so the charging circuit comprising the transistors M3 and M4 are disabled. Therefore, the enhancement circuit 370 can be regarded as having no substantial operation at this time.

When the supply voltage VCCINT is greater than the supply voltage VCCIO, that is the GPIO driver 100 performs the under-drive operation, the enhancement circuit 370 is enabled, and the enhancement circuit 370 serves as a buffer and dominates the operation of the level shifter module 120. Specifically, when the supply voltage VCCINT is greater than the supply voltage VCCIO, the transistor Ml is enabled while the transistor M2 is disabled, so that the power switch 140 provides the supply voltage VCCINT to the level-shifting circuit 360. The transistor M3 controlled by the power selection signal PWRSEL is enabled, so enhancement circuit 370 serves as a buffer to receive the inverted first signal V1B to generate the second signal V2, wherein the voltage levels of the second signal V2 and the first signal V1 are substantially the same. In addition, the level-shifting circuit 360 can also serve as buffer, and because the latency of the level-shifting circuit 360 is greater than the latency of the enhancement circuit 370, the enhancement circuit 370 dominates the operation of the level shifter operation 120.

In this embodiment, when the supply voltage VCCINT is greater than the supply voltage VCCIO, all the components within the level-shifter module 120 are supplied by the supply voltage VCCINT, so the second signal V2 and the first signal V1 have the same or similar voltage levels. Therefore, the voltage level of the second voltage V2 will be reduced after passing through the post-driver 130 supplied by the supply voltage VCCIO.

It is noted that the detailed circuit structure shown in FIG. 3 is for illustrative, not a limitation of the present invention. For example, the level-shifting circuit 360 can be replaced by any other type of level-shifting circuit, the transistors M3 and M4 of the enhancement circuit 370 may be replaced by any other charging circuit to charge the node N3 according to the power selection signal PWRSEL and the first signal V1 or inverted first signal V1B, and the transistor M5 of the enhancement circuit 370 can be replaced by any other discharging circuit capable of discharging the node N3 according to the first signal V1 or inverted first signal VIB. In other words, as long as the level shifter module 120 has a level-boosting operation when the supply voltage VCCINT is lower than the supply voltage VCCIO, and the level shifter module 120 serves as a buffer when the supply voltage VCCINT is greater than the supply voltage VCCIO, the level-shifting circuit 360 and the enhancement circuit 370 can have different circuit designs.

Briefly summarized, in the GPIO driver of the present invention, when the GPIO performs the under-drive operation, the level shifter module operates as a buffer instead of performing level-shifting operation, so the signal propagation delay caused by the level shifter module will be greatly reduced to meet the requirements for chip-to-chip communications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A general-purpose input/output (GPIO) driver, comprising:
a control logic, configured to receive an input signal to generate a first signal, wherein the control logic is supplied by a first supply voltage;
a level shifter module, configured to receive the first signal to generate a second signal; and
a post-driver, configured to receive the second signal to generate an output signal, wherein the post-driver is supplied by a second supply voltage;
wherein when the first supply voltage is lower than the second supply voltage, the level shifter module performs a level-boosting operation to increase a voltage level of the first signal to generate the second signal; and when the first supply voltage is greater than the second supply voltage, the level shifter module operates as a buffer, and the voltage level of the second signal is the same as the voltage level of the first signal.

2. The GPIO driver of claim 1, wherein the level shifter module comprises:
a level-shifting circuit; and
an enhancement circuit, coupled to the level-shifting circuit;
wherein when the first supply voltage is lower than the second supply voltage, the level-shifting circuit performs the level-boosting operation to increase the voltage level of the first signal to generate the second signal, and the enhancement circuit is disabled; and when the first supply voltage is greater than the second supply voltage, the enhancement circuit operates as the buffer and dominates an operation of the level shifter module.

3. The GPIO driver of claim 2, wherein an output terminal of the level-shifting circuit and an output terminal of the enhancement circuit are connected together to serve as an output terminal of the level shifter module.

4. The GPIO driver of claim 2, further comprising:
a power switch, configured to provide one of the first supply voltages and the second supply voltage to the level-shifting circuit according to a power selection signal.

5. The GPIO driver of claim 4, wherein when the power selection signal indicates that the first supply voltage is lower than the second supply voltage, the power switch provides the second supply voltage to the level-shifting circuit; and when the power selection signal indicates that the first supply voltage is greater than the second supply voltage, the power switch provides the first supply voltage to the level-shifting circuit.

6. The GPIO driver of claim 4, wherein the enhancement circuit is supplied by the first supply voltage.

7. The GPIO driver of claim 6, wherein the enhancement circuit comprise:
a charging circuit, coupled between the first supply voltage and an output terminal of the enhancement circuit, configured to charge the output terminal of the enhancement circuit according to the power selection signal and the first signal when the power selection signal indicates that the first supply voltage is greater than the second supply voltage; and
a discharging circuit, coupled between a ground voltage and the output terminal of the enhancement circuit, configured to discharge the output terminal of the enhancement circuit according to the first signal.

8. The GPIO driver of claim 7, wherein the charging circuit comprises:
a first P-type transistor, coupled to the first supply voltage, wherein the first P-type transistor is controlled by the power selection signal; and
a second P-type transistor, coupled between the first P-type transistor and the output terminal of the enhancement circuit, wherein the second P-type transistor is controlled according to the first signal; and
the discharging circuit comprises:
an N-type transistor, coupled between a ground voltage and the output terminal of the enhancement circuit, wherein the N-type transistor is controlled according to the first signal.

9. The GPIO driver of claim 4, further comprising:
a power selection signal generator, configured to compare the first supply voltage and the second supply voltage to generate the power selection signal.
